(19) United States
(12) Patent Application Publication
(10) Pub. No.: US 2007/0146992 A1
(43) Pub. Date: Jun. 28, 2007

(54) Anti-static structure

(76) Inventors: Cheng-Hsiung Chang, Taipei Hsien (TW); Chia-Wang Chiu, Taipei Hsien (TW); Kuo-Lung Shih, Taipei Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/316,935

(22) Filed: Dec. 27, 2005

(51) Int. Cl. H05K 7/20

(52) U.S. Cl. 361/695

(57) ABSTRACT

An anti-static structure applied to a computer includes a chassis made of conductive material, a main board secured to the chassis having a CPU electrically connected thereto, a heat sink arranged on the CPU having a top surface, and a static transmission wire electrically connecting the top surface of the heat sink to the main board.

### BACKGROUND OF THE INVENTION

1. Field of the Invention

The present invention relates to an anti-static structure, and particularly to an anti-static structure applied to a computer in order to discharge the static electricity generated by the heat sink.

2. Description of the Related Art

A computer includes a CPU. As the CPU operates at faster levels to process greater quantities of data, the higher it's temperature becomes. Therefore, a cooler is provided to dissipate the heat generated therefrom to decrease the temperature of the CPU.

Static electricity is generated through the normal operation of a computer. However, if too much static electricity is present at one time, it will force the computer to shut down or even damage the CPU. If this electrostatic discharge (ESD) can be resolved the electronic components of the computer, especially the CPU, will be enabled to operate normally.

However, the source of the static electricity not only comes from the computer; it also comes from the exterior environment, even though the heat sink that decreases the temperature of the CPU generates static electricity.

Referring to FIG. 1, a conventional computer includes a chassis 1 made of conductive material, a main board 2 and a heat sink 3. The main board 2 has a CPU 21 arranged thereof and is arranged on the chassis 1 via a plurality of securing members 22. The heat sink 3 includes a fan 31 and a body 32 having a plurality of fins 321. The body 32 is disposed on the CPU 21. The fan 31 is connected to the body 32 via a plurality of screw members 312. In addition, a power source 311 of the fan 31 electrically connects with the main board 2 to supply power to the fan 31.

Reference is made to FIG. 2, which is a cross-sectional profile of the chassis 1 arranged inside a casing 9 of the computer. When the fan 31 operates and static electricity is generated, the static electricity is transmitted to the CPU 21 via the body 32 and even to the main board 2 via the CPU 21. As a result, the static electricity is spread all over the main board 2 including the relative electrical components, and the system will shut down and the electrical components may even burn out.

### SUMMARY OF THE INVENTION

An anti-static structure is provided with a static transmission wire connected between a top of a heat sink and a main board to carry static electricity away, thereby the shutting down of the system and the burning out of electrical components is avoided.

An anti-static structure applied to a computer includes a chassis made of conductive material, a main board secured to the chassis and having a CPU electrically connected thereto, a heat sink arranged on the CPU having a top surface, and a static transmission wire electrically connecting the top surface of the heat sink to the main board.

An anti-static structure applied to a computer includes a chassis made of conductive material, a main board secured to the chassis and having a CPU electrically connected thereto, a heat sink arranged on the CPU, a fan arranged over the heat sink and having a top surface, and a static transmission wire electrically connected between the top surface of the fan and the main board.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a perspective view of a partial part of a conventional computer;

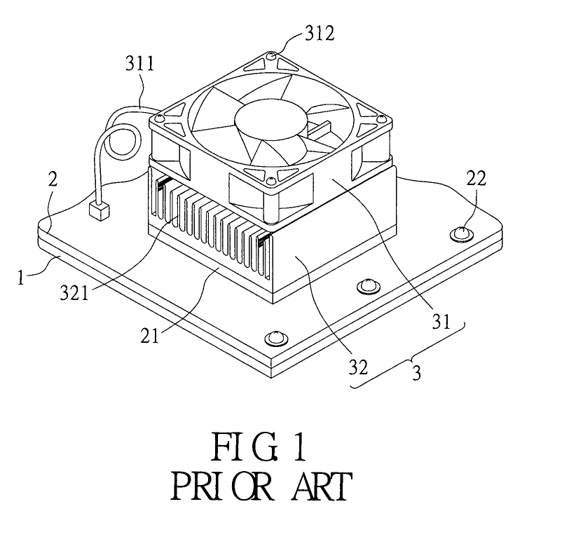

FIG. 2 is a cross-sectional profile of a chassis of the conventional computer;

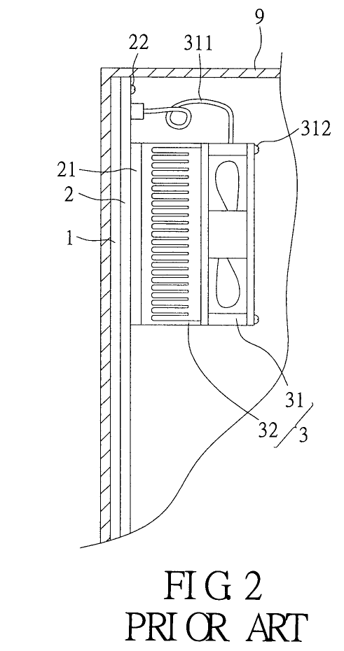

FIG. 3 is a perspective view of an anti-structure according to the present invention; and

FIG. 4 is a cross-sectional profile of the anti-structure arranged inside a part of a computer according to the present invention.

### DETAILED DESCRIPTION OF PREFERRED EMBODIMENTS

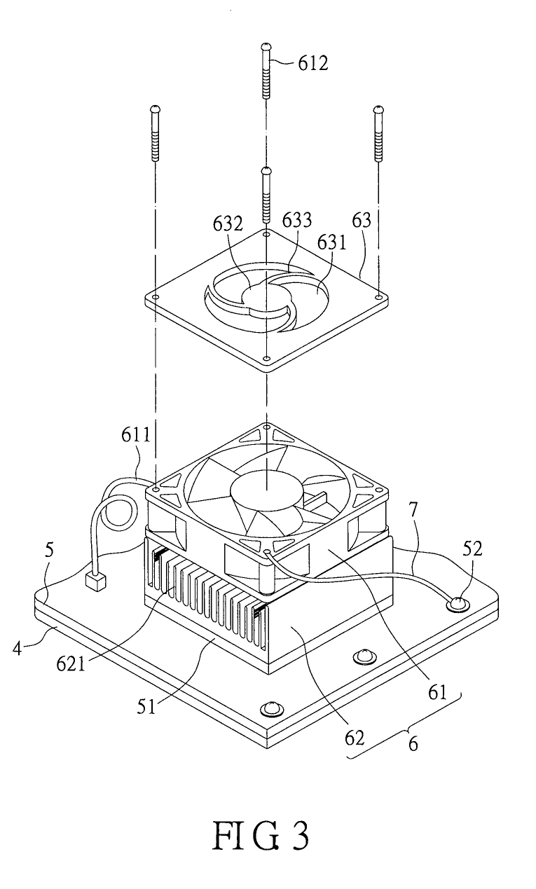

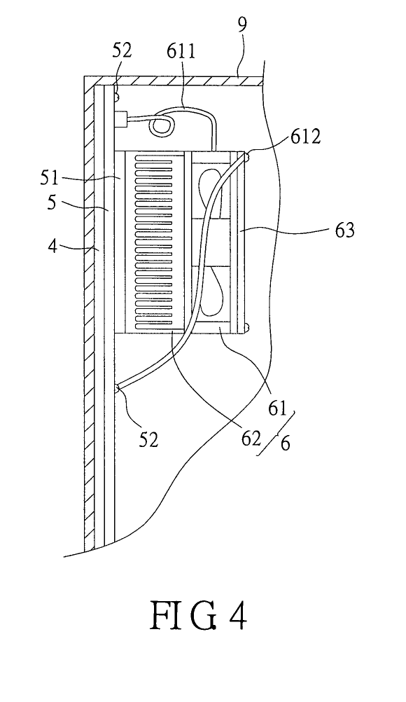

Referring to FIGS. 3 and 4, an anti-static structure according to the present invention includes a chassis 4, a main board 5, a heat sink 6 and a static transmission wire 7.

The chassis 4 is disposed inside a casing 9 of a computer. The chassis 4 and the casing 9 are made of materials so as to electrically connect to each other.

The main board 5 includes a CPU 51 and other electronic components that are not shown. The main board 5 is connected to the chassis 4 via a plurality of securing members 52, and these securing members 52 can be rivet-jointing members, tongue-and-groove jointing members or screw members.

The heat sink 6 includes a fan 61 and a body 62. The body 62 has a plurality of fins 621 arranged thereof in an integration manner (in this embodiment) or in an attachment manner (not shown). The fan 61 is arranged over the CPU 51. The fan 61 has a top surface and a cover 63 arranged over the top surface. The cover 63 further has a ventilation portion 631 communicating with the fan 61, a mediate portion 632, especially, arranged inside the ventilation portion 631 in order to correspond to a shaft of the fan 61, and a plurality of connection portions 633 linking the cover 631 and the mediate portion 632. The cover 63 with the mediate portion 632 and the connection portions 633 are made of conductive material for transmitting static electricity. In a preferred embodiment, a plurality of screw members 612 are arranged among the cover 63, the fan 61, and the body 62 for mechanical connection. In addition, a power source 611 of the fan 61 is electrically connected to the main board 5.

The static transmission wire 7 has a first end and a second end. The first end thereof connects with the cover 63 of the heat sink 6 via one of the screw members 612 to form an electrical and mechanical connection. The second end thereof connects to the main board 5 via one of the securing members 52 to form an electrical and mechanical connection. The static transmission wire 7 is preferably stretched out so as to be a straight wire, or at least twisted into an S shape such as a curved wire.

Referring to FIG. 4, the chassis 4 with the main board 5 are arranged inside the casing 9 of the computer. When the computer is turned on, the fan 61 operates and generates static electricity. The static electricity can be transmitted to the chassis 4 and even the casing 9 via the cover 63, the static transmission wire 7 and the respective securing member 52. Regardless of whether the static electricity is finally transmitted outwards via the chassis or the casing 9, the trouble of the system shutting down or the electronic components, such as the CPU, burning out, can be solved completely.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. An anti-static structure applied to a computer, comprising:
a chassis made of conductive material;
a main board secured to the chassis and having a CPU electrically connected thereto;
a heat sink arranged on the CPU having a top surface; and
a static transmission wire electrically connecting the top surface of the heat sink and the main board.

2. The anti-static structure as claimed in claim 1, wherein the heat sink includes a cover arranged on the top surface thereof, and the cover is made of conductive material; the static transmission wire has a first end and a second end, and the first end thereof electrically connects with the cover.

3. The anti-static structure as claimed in claim 1, further including a plurality of securing members arranged between the main board and the chassis for mechanical connection; the static transmission wire has a first end and a second end, and the second end thereof electrically connects with one of the securing members.

4. The anti-static structure as claimed in claim 1, wherein the static transmission wire is a curved wire.

5. An anti-static structure applied to a computer, comprising:
a chassis made of conductive material;
a main board secured to the chassis and having a CPU electrically connected thereto;
a heat sink arranged on the CPU;
a fan arranged over the heat sink and having a top surface; and
a static transmission wire electrically connecting the top surface of the fan and the main board.

6. The anti-static structure as claimed in claim 5, wherein the heat sink includes a cover that is made of conductive material and arranged on the top surface thereof, and the cover has a ventilation portion communicating with the fan; the static transmission wire has a first end and a second end, and the first end thereof electrically connects with the cover.

7. The anti-static structure as claimed in claim 6, further including a plurality of screw members arranged among the cover, the fan and the body for mechanical connection; the static transmission wire has a first end and a second end, and the second end thereof electrically connects with the cover via one of the screw members.

8. The anti-static structure as claimed in claim 6, wherein the cover includes a mediate portion arranged inside the ventilation portion and corresponding to a shaft of the fan, and a plurality of connection portions linking the cover and the mediate portion, wherein the cover, the mediate portion and the connection portions are made of conductive material.

9. The anti-static structure as claimed in claim 5, further including a plurality of securing members arranged between the main board and the chassis for mechanical connection; the static transmission wire has a first end and a second end, and the second end thereof electrically connects with one of the securing members.

10. The anti-static structure as claimed in claim 5, wherein the static transmission wire is a curved wire.

11. The anti-static structure as claimed in claim 5, wherein the body of the heat sink includes a plurality of fins attached thereto.
